(19) United States
(12) Patent Application Publication
(10) Pub. No.: US 2024/0091968 A1
(43) Pub. Date: Mar. 21, 2024

(54) BLADE FOR SAWING A PANEL LEVEL PACKAGE AND METHOD OF SAWING A PANEL LEVEL PACKAGE USING THE SAME

(71) Applicant: SAMSUNG ELECTRONICS CO., LTD., Suwon-si (KR)

(72) Inventors: Younhwan Shin, Suwon-si (KR); Dongju Jang, Suwon-si (KR)

(73) Assignee: SAMSUNG ELECTRONICS CO., LTD., Suwon-si (KR)

(21) Appl. No.: 18/132,169

(22) Filed: Apr. 7, 2023

(30) Foreign Application Priority Data
Sep. 15, 2022 (KR) 10-2022-0116443

(51) Int. Cl. B26D 1/00; B26D 1/06

(52) U.S. Cl. CPC B26D 1/0006; B26D 1/065; B26D 2001/006

(57) ABSTRACT

A blade for sawing a panel, including a first blade portion configured to saw the panel along a first direction, wherein the panel includes a plurality of panel level packages (PLPs) arranged in the first direction and a second direction which is substantially perpendicular to the first direction; and a second blade portion arranged on an upper surface of the first blade portion, and configured to saw the panel along the second direction, wherein a width of the second blade portion is greater than a width of the first blade portion.

### CROSS-REFERENCE TO RELATED APPLICATION

This application is based on and claims priority under 35 USC § 119 to Korean Patent Application No. 10-2022-0116443, filed on Sep. 15, 2022 in the Korean Intellectual Property Office, the disclosure of which are herein incorporated by reference in its entirety.

### BACKGROUND

### 1. Field

The disclosure relates to a blade for sawing a panel level package and a method of sawing a panel level package using the same. More particularly, the disclosure relates to a blade for sawing a panel with a plurality of panel level packages and a method of sawing a panel using the blade.

### 2. Description of Related Art

Generally, a panel level package (PLP) may include a panel having a plurality of cavities, a plurality of semiconductor chips received in the cavities, a redistribution layer (RDL) formed on a lower surface of the panel, etc. After completing a packaging process, portions of the panel between the PLP may be sawed using a blade.

In some implementations, the blade may have a uniform width. The blade may saw the panel once along a short axial direction, or may saw the panel twice along a long axial direction. Thus, a one-sided wear may be generated at the blade. As a result, a use period of the blade may be decreased, which may cause the blade to be frequently exchanged for a new one.

### SUMMARY

Provided is a blade for sawing a panel level package having a long use period.

Also provided is a method of sawing a panel level package using the blade.

Additional aspects will be set forth in part in the description which follows and, in part, will be apparent from the description, or may be learned by practice of the presented embodiments.

In accordance with an aspect of the disclosure, a blade for sawing a panel includes a first blade portion configured to saw the panel along a first direction, wherein the panel includes a plurality of panel level packages (PLPs) arranged in the first direction and a second direction which is substantially perpendicular to the first direction; and a second blade portion arranged on an upper surface of the first blade portion, and configured to saw the panel along the second direction, wherein a width of the second blade portion is greater than a width of the first blade portion.

In accordance with an aspect of the disclosure, a blade for sawing a panel includes a first blade portion configured to saw a rectangular panel along a first direction, wherein the panel includes a plurality of panel level packages (PLPs) arranged in the first direction and a second direction which is substantially perpendicular to the first direction; a second blade portion arranged on an upper surface of the first blade portion, and configured to saw the panel along the second direction, wherein a width of the second blade portion is greater than a width of the first blade portion; and a lifter configured to lift the first blade portion and the second blade portion, wherein a gap between the PLPs along the first direction is wider than a gap between the PLPs along the second direction.

In accordance with an aspect of the disclosure, a method of sawing a panel includes sawing a panel, along a first direction using a first blade, wherein the panel includes a plurality of panel level packages (PLPs) arranged in the first direction and a second direction substantially perpendicular to the first direction; downwardly moving a second blade to a sawing position corresponding to the panel; and sawing the panel along the second direction using the second blade, wherein the second blade is arranged on an upper surface of the first blade, wherein a width of the second blade is greater than a width of the first blade.

### BRIEF DESCRIPTION OF DRAWINGS

Example embodiments will be more clearly understood from the following detailed description taken in conjunction with the accompanying drawings. FIGS. 1 to 7 represent non-limiting, example embodiments as described herein.

FIG. 1 is a plan view illustrating a panel with a panel level package to which a blade is applied, according to embodiments;

FIG. 2 is a cross-sectional view illustrating a blade, according to embodiments;

FIG. 3 is a flow chart illustrating a method of sawing a panel using the blade of FIG. 2, according to embodiments; and

FIGS. 4 to 7 are plan views and cross-sectional views illustrating a method of sawing a panel using the blade of FIG. 2, according to embodiments.

### DETAILED DESCRIPTION OF EMBODIMENTS

Hereinafter, example embodiments will be explained in detail with reference to the accompanying drawings.

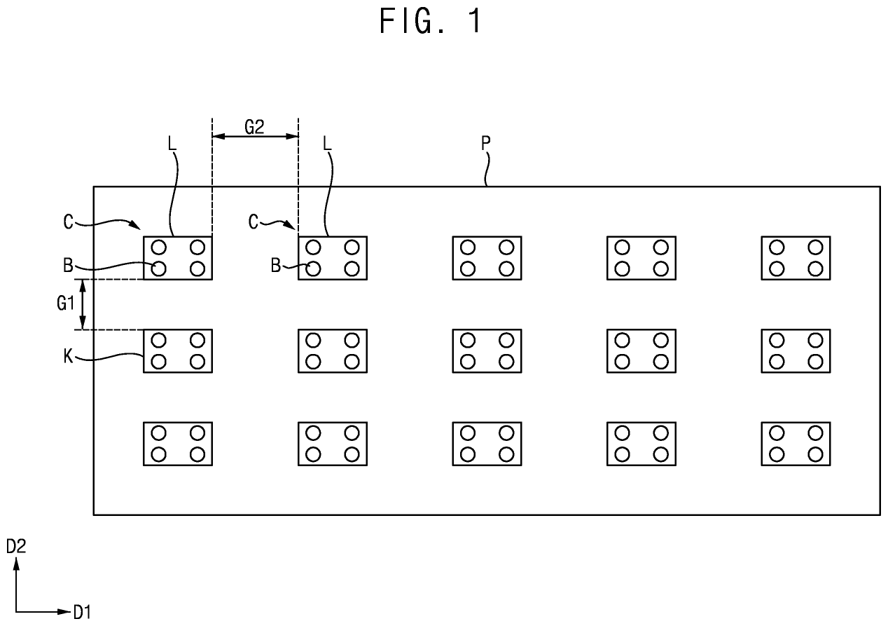

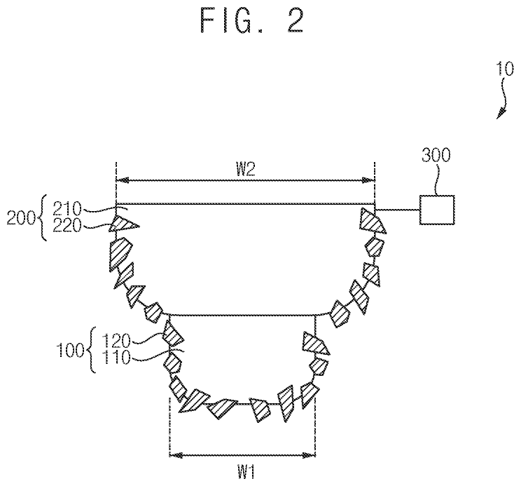

FIG. 1 is a plan view illustrating a panel with a panel level package to which a blade may be applied, according to embodiments. FIG. 2 is a cross-sectional view illustrating a blade in accordance with example embodiments.

Referring to FIG. 1, according to embodiments a blade 10 may be applied to a panel level package (PLP) K. The PLP K may be formed on a panel P or a strip, and the PLP K may include a plurality of semiconductor chips, a redistribution layer (RDL) L and one or more conductive bumps B. The panel P may include a plurality of cavities C. The cavities C may be arranged in a first direction D1 and a second direction D2. The first direction D1 and the second direction D2 may be substantially perpendicular to each other.

In example embodiments, the panel P may have a rectangular shape. Thus, the panel P may have a long axial direction and a short axial direction. The long axial direction may correspond to the first direction D1. The short axial direction D2 may correspond to the second direction D2. A second gap G2 between the cavities C along the long axial direction may be wider than a first gap G1 between the cavities C along the short axial direction. In embodiments, the second gap G2 between the cavities C along the long axial direction may be narrower than the first gap G1 between the cavities C along the short axial direction. Further, the second gap G2 between the cavities C along the long axial direction may be substantially the same as the first gap G1 between the cavities along the short axial direction.

In embodiments, the panel P may have a square shape. In this case, the cavities may be arranged along the first direction D1 and the second direction D2 by the first gap G1 and the second gap G2.

The semiconductor chips may be received in the cavities C. As mentioned above, because the second gap G2 between the cavities C along the long axial direction may be wider than the first gap G1 between the cavities C along the short axial direction, the second gap G2 between the semiconductor chips along the long axial direction may also be wider than the first gap G1 between the semiconductor chips along the short axial direction. That is, the gaps between the semiconductor chips may be determined in accordance with the gaps between the cavities C. As a result, the second gap G2 between the PLPs K along the long axial direction may also be wider than the first gap G1 between the PLP K along the short axial direction.

The RDL L may be formed on a lower surface of the panel P. The RDL L may be electrically connected with the semiconductor chips. The conductive bumps B may be mounted on a lower surface of the RDL L.

After a packaging process for forming the PLP K may be completed, the panel P may be sawed using the blade 10 along the first direction D1 and the second direction D2 to singulate the PLPs K.

Referring to FIG. 2, the blade 10 may include a first blade 100, a second blade 200 and a lifter 300. In embodiments, the first blade 100 may be or include a first portion of the blade 10, and the second blade 200 may be or include a second portion of the blade 10.

The first blade 100 may saw the panel P along the first direction D1. For example, the first blade 100 may saw the panel P along the first direction D1 when the blade 10 is positioned at a first height H1.

In example embodiments, the first blade 100 may have a first width W1. For example, the first width W1 of the first blade 100 may be about 160 μm to about 220 μm, however embodiments are not limited thereto. The first blade 100 may include a first blade head 110, a plurality of first grits 120 and an adhesive.

The first blade head 110 may have a rectangular shape, however embodiments are not limited thereto. The first blade head 110 may have the first width W1. Thus, the first blade head 110 may have an upper surface, a lower surface and side surfaces. As an example, both lower ends of the first blade head 110, which may include for example corners or connection portions of the first blade head 110 between the lower surface and the side surfaces, may have a rounded shape, however embodiments are not limited thereto. For example, in embodiments one or both of the lower ends of the first blade head 110 may not be rounded.

The first grits 120 may be configured to saw the panel P along the first direction D1. The first grits 120 may be arranged at the lower surface and the side surfaces of the first blade head 110. In embodiments, the first grits 120 may not be arranged at the upper surface of the first blade head 110. The first grits 120 may be attached to the first blade head 110 using the adhesive. The first grits 120 may include diamond, however embodiments are not limited thereto. The adhesive may include copper, tin, tungsten, nickel, etc., however embodiments are not limited thereto.

The second blade 200 may saw the panel P along the second direction D2. For example, the second blade 200 may saw the panel P along the second direction D2 when the blade 10 is positioned at a second height H2. The second height H2 may be lower than the first height H1. In embodiments, the height H1 and the height H2 may specify, for example, a position of the blade 10 with respect to the panel P in a vertical direction which is perpendicular to the directions D1 and D2.

The second blade 200 may be arranged on the upper surface of the first blade 100. That is, a central portion of a lower surface of the second blade 200 may make contact with the upper surface of the first blade 100. Thus, an edge portion of the lower surface of the second blade 200 may be downwardly exposed. In example embodiments, the first blade 100 and the second blade 200 may be one body. The blade 10 including the first blade 100 and the second blade 200 may be formed by processes including a grinding process, a polishing process, a dressing process, etc.

In example embodiments, the second blade 200 may have a second width W2. The second width W2 may be wider than the first width W1. As a result, according to embodiments the blade 10 may have two-class sawing widths. Because the second width W2 of the second blade 200 may be wider than the first width W1 of the first blade 100, as mentioned above, the edge portion of the lower surface of the second blade 200 may be downwardly exposed. For example, the second width W2 of the second blade 200 may be about 220 μm to about 320 μm, however embodiments are not limited thereto. The second blade 200 may include a second blade head 210, a plurality of second grits 220 and an adhesive.

The second blade head 210 may have a rectangular shape, however embodiments are not limited thereto. The second blade head 210 may have the second width W2. Thus, the second blade head 210 may have an upper surface, a lower surface and side surfaces. For example, both lower ends of the second blade head 210, which may include for example corners or connection portions of the second blade head 210 between the lower surface and the side surfaces, may have a rounded shape. In embodiments, the second blade head 210 may not have the rounded both lower ends.

The second grits 220 may be configured to saw the panel P along the second direction D2. The second grits 220 may be arranged at the edge portion of the lower surface and the side surfaces of the second blade head 210. In embodiments, the second grits 220 may not be arranged at the upper surface of the second blade head 210. The second grits 220 may be attached to the second blade head 210 using the adhesive. The second grits 220 may include diamond, however embodiments are not limited thereto. The adhesive may include copper, tin, tungsten, nickel, etc., however embodiments are not limited thereto.

The lifter 300 may be configured to lift or lower the blade 10. For example, the lifter 300 may lift or lower the blade 10 to the first height H1 in order to place the first blade 100 in a position to cut the panel P. Further, the lifter 300 may lift or lower the blade 10 to the second height H2 in order to place the second blade 200 in a position to cut the panel P. As mentioned above, because the second height H2 may be lower than the first height H1, the lifter 300 may downwardly move, or otherwise lower, the blade 10 from the first height H1 to the second height H2. The lifter 300 may include a motor, a cylinder, etc., however embodiments are not limited thereto.

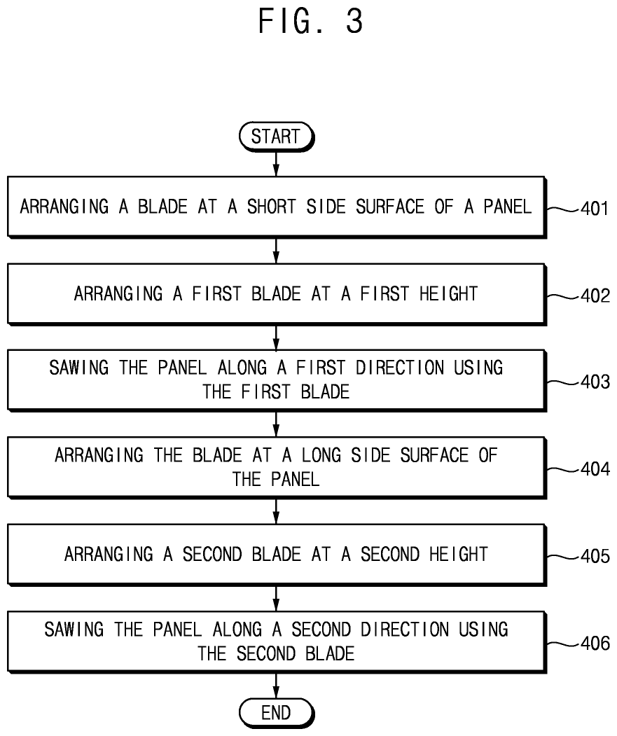

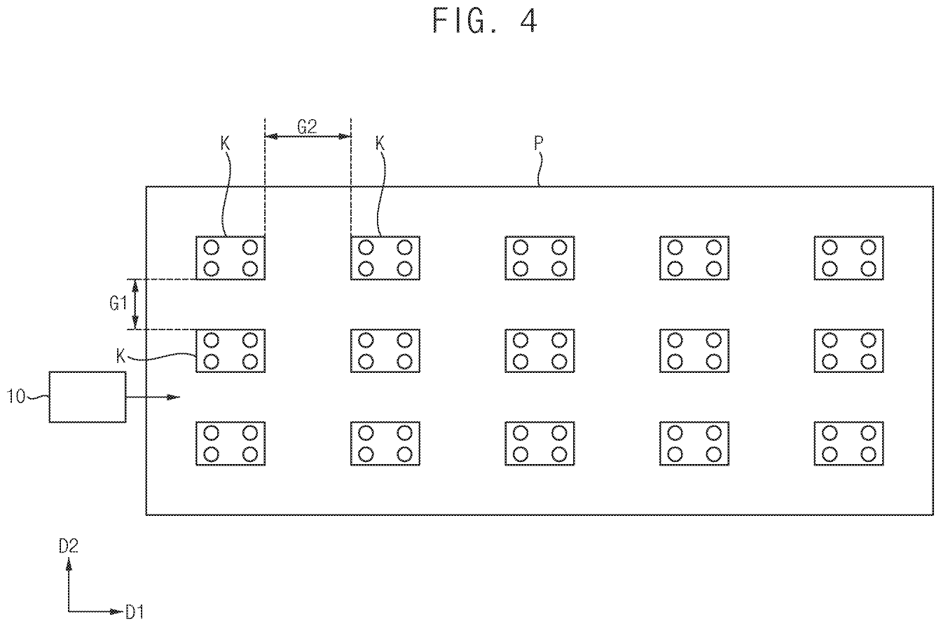

FIG. 3 is a flow chart illustrating a process 400 of sawing a panel using the blade in FIG. 2. FIGS. 4 to 7 are plan views and cross-sectional views illustrating a method of sawing a panel using the blade in FIG. 2.

Referring to FIGS. 3 and 4, at operation 401, the blade 10 may be placed at a short side surface of the panel P. For example, the panel P may have a rectangular shape with a short side and a long side, and the blade 10 may be placed at a surface of the short side.

At operation 402, the lifter 300 may upwardly move, or otherwise lift, the blade 10 to position the blade 10 at the first height H1.

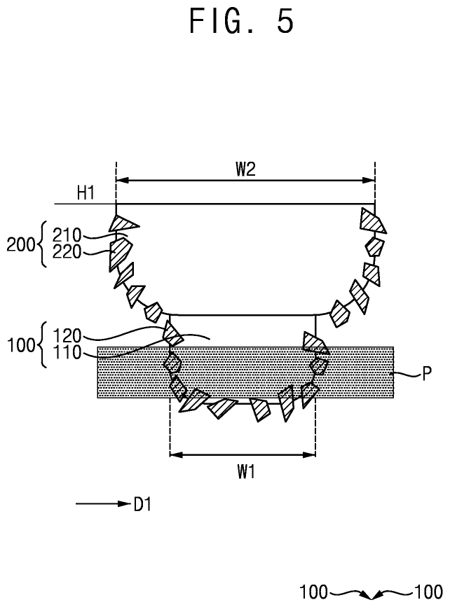

Referring to FIGS. 3 and 5, at operation 403, the first blade 100 may be horizontally moved along the first direction D1 with the blade 10 at the first height H1 to saw the panel P with the first blade 100 along the first direction D1.

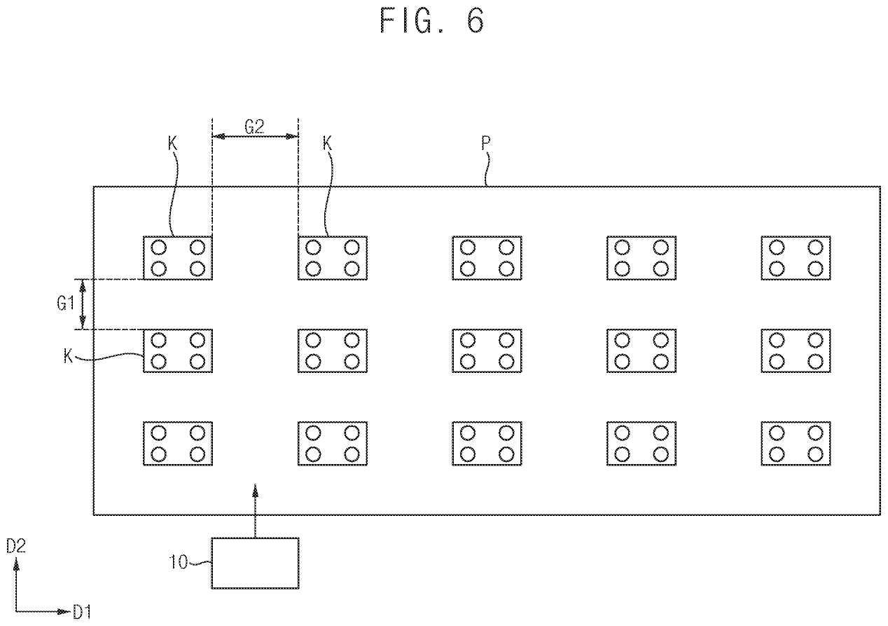

Referring to FIGS. 3 and 6, at operation 405, the blade 10 may be placed at a long side surface of the panel P.

At operation 406, the lifter 300 may downwardly move, or otherwise lower, the blade 10 from the first height H1 to the second height H2.

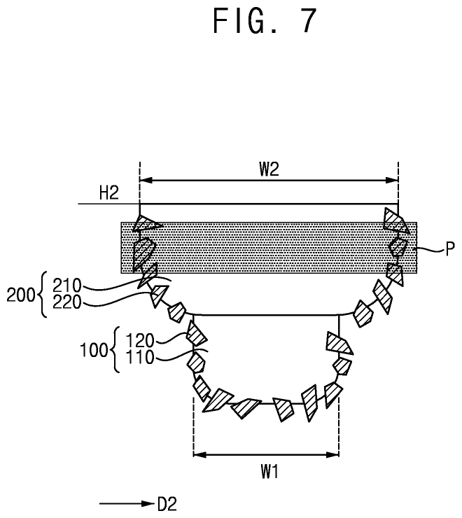

Referring to FIGS. 3 and 7, in step ST450, the second blade 200 may be horizontally moved along the second direction with the blade 10 at the second height H2 to saw the panel P with the second blade 200 along the second direction D2. That is, the sawing of the panel P along the second direction D2 may be performed by a single sawing process using the second blade 200.

Therefore, the PLPs K may be singulated or otherwise separated from each other by the sawing processes of the blade 10 along the first direction D1 and the second direction D2.

According to example embodiments, the blade may include the first blade and the second blade having the width wider than the width of the first blade to saw the panel one time using the blade. Thus, a one-sided wear of the blade may be reduced in order to extend a use period of the blade.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A blade for sawing a panel, the blade comprising:
a first blade portion configured to saw the panel along a first direction, wherein the panel includes a plurality of panel level packages (PLPs) arranged in the first direction and a second direction which is substantially perpendicular to the first direction; and
a second blade portion arranged on an upper surface of the first blade portion, and configured to saw the panel along the second direction,
wherein a width of the second blade portion is greater than a width of the first blade portion.

2. The blade of claim 1, wherein the panel has a rectangular shape,
wherein the first direction comprises a first axial direction of the panel,
wherein the second direction comprises a second axial direction of the panel, and
wherein a length of the panel in the first axial direction is greater than a length of the panel in the second axial direction.

3. The blade of claim 1, wherein a gap between the PLPs along the first direction is wider than a gap between the PLPs along the second direction.

4. The blade of claim 1, wherein the first blade portion comprises:
a first blade head; and
a plurality of first grits arranged on a surface of the first blade head.

5. The blade of claim 4, wherein the first blade head has a rectangular shape, and wherein lower ends of the first blade head have a rounded shape.

6. The blade of claim 5, wherein the plurality of first grits are arranged on side surfaces and a lower surface of the first blade head.

7. The blade of claim 1, wherein the width of the first blade portion is in a range of about 160 μm to about 220 μm.

8. The blade of claim 1, wherein the second blade portion comprises:
a second blade head arranged on an upper surface of the first blade portion; and
a plurality of second grits arranged on a surface of the second blade head.

9. The blade of claim 8, wherein the second blade head has a rectangular shape, and
wherein the second blade head comprises a lower surface on the upper surface of the first blade portion.

10. The blade of claim 9, wherein the plurality of second grits are arranged on side surfaces of an edge portion of the lower surface of the second blade head.

11. The blade of claim 1, wherein the width of the second blade portion is in a range of about 220 μm to about 320 μm.

12. The blade of claim 1, further comprising a lifter configured to lift the first blade portion and the second blade portion.

13. A blade for sawing a panel, the blade comprising:
a first blade portion configured to saw a rectangular panel along a first direction, wherein the panel includes a plurality of panel level packages (PLPs) arranged in the first direction and a second direction which is substantially perpendicular to the first direction;
a second blade portion arranged on an upper surface of the first blade portion, and configured to saw the panel along the second direction, wherein a width of the second blade portion is greater than a width of the first blade portion; and
a lifter configured to lift the first blade portion and the second blade portion,
wherein a gap between the PLPs along the first direction is wider than a gap between the PLPs along the second direction.

14. The blade of claim 13, wherein the first direction comprises a first axial direction of the panel,
wherein the second direction comprises a second axial direction of the panel, and
wherein a length of the panel in the first axial direction is greater than a length of the panel in the second axial direction.

15. The blade of claim 13, wherein the first blade portion comprises:
a rectangular first blade head having rounded lower ends; and
a plurality of first grits arranged on side surfaces and a lower surface of the first blade head.

16. The blade of claim 13, wherein the width of the first blade portion is in a range of about 160 μm to about 220 μm.

17. The blade of claim 13, wherein the second blade portion comprises:
a rectangular second blade head having rounded lower ends arranged on the upper surface of the first blade portion; and
a plurality of second grits arranged on side surfaces and an edge portion of a lower surface of the second blade head.

18. The blade of claim 13, wherein the width of the second blade portion is in a range of about 220 μm to about 320 μm.

19. A method of sawing a panel, the method comprising:
sawing a panel, along a first direction using a first blade, wherein the panel includes a plurality of panel level packages (PLPs) arranged in the first direction and a second direction substantially perpendicular to the first direction;
downwardly moving a second blade to a sawing position corresponding to the panel; and
sawing the panel along the second direction using the second blade,
wherein the second blade is arranged on an upper surface of the first blade,
wherein a width of the second blade is greater than a width of the first blade.

20. The method of claim 19, wherein the panel has a rectangular shape,
wherein the first direction comprises a first axial direction of the panel,
wherein the second direction comprises a second axial direction of the panel,
wherein a length of the panel in the first axial direction is greater than a length of the panel in the second axial direction, and
wherein a gap between the PLPs along the first direction is wider than a gap between the PLPs along the second direction.
